(19) United States
(12) Patent Application Publication
(10) Pub. No.: US 2026/0150579 A1
(43) Pub. Date: May 28, 2026

(54) LIQUID EJECTING HEAD AND LIQUID EJECTING APPARATUS

(71) Applicant: SEIKO EPSON CORPORATION, Tokyo (JP)

(72) Inventors: Yoshiki YANO, CHINO-SHI (JP); Koji OHASHI, MATSUMOTO-SHI (JP); Daisuke NAGANO, MATSUMOTO-SHI (JP); Nobuaki ITO, SUWA-SHI (JP); Shu OKADA, CHINO-SHI (JP)

(21) Appl. No.: 19/396,654

(22) Filed: Nov. 21, 2025

(30) Foreign Application Priority Data
Nov. 25, 2024 (JP) 2024-204483

(51) Int. Cl. H10N 30/00; B41J 2/14; B41J 2/16; H10N 30/20; H10N 30/853; H10N 30/87

(52) U.S. Cl. CPC H10N 30/708; B41J 2/14233; B41J 2/161; H10N 30/2047; H10N 30/8542; H10N 30/8548; H10N 30/872; B41J 2002/14491

(57) ABSTRACT

A liquid ejecting head includes a pressure chamber substrate that includes a plurality of pressure chambers arranged in a first direction, a vibration plate disposed on the pressure chamber substrate, a first electrode disposed on the vibration plate, a piezoelectric layer disposed on the first electrode, a second electrode disposed on the piezoelectric layer, and a seed layer positioned between the piezoelectric layer and the vibration plate and configured to control an orientation of the piezoelectric layer, in which the piezoelectric layer has a first region that does not overlap the first electrode in the first direction and a second region that overlaps the first electrode in the first direction, and a thickness of a portion of the seed layer corresponding to the second region is thicker than a thickness of a portion of the seed layer corresponding to the first region.

The present application is based on, and claims priority from JP Application Serial Number 2024-204483, filed Nov. 25, 2024, the disclosure of which is hereby incorporated by reference herein in its entirety.

### BACKGROUND

### 1. Technical Field

The present disclosure relates to a liquid ejecting head and a liquid ejecting apparatus.

### 2. Related Art

In a liquid ejecting head in which a vibration plate, a first electrode, a piezoelectric layer, and a second electrode are laminated in this order on a pressure chamber substrate having a plurality of pressure chambers, a seed layer for controlling an orientation of the piezoelectric layer may be provided between the piezoelectric layer and the vibration plate. For example, JP-A-2017-37932 describes a method of forming a single seed layer uniformly on a patterned first electrode, and then forming a piezoelectric layer on the seed layer.

In the configuration of JP-A-2017-37932, the seed layer is provided not only in an active portion, which is a portion overlapping the first electrode of the piezoelectric layer, but also in an inactive portion, which is a portion not overlapping the first electrode of the piezoelectric layer. Therefore, the orientation of the inactive portion can be enhanced as compared with an aspect in which the seed layer is not provided in the inactive portion, but there is room for improvement in reducing cracks.

### SUMMARY

According to an aspect of the present disclosure, there is provided a liquid ejecting head including: a pressure chamber substrate that includes a plurality of pressure chambers arranged in a first direction, a vibration plate disposed on the pressure chamber substrate, a first electrode disposed on the vibration plate, a piezoelectric layer disposed on the first electrode, a second electrode disposed on the piezoelectric layer, and a seed layer positioned between the piezoelectric layer and the vibration plate and configured to control an orientation of the piezoelectric layer, in which the piezoelectric layer has a first region that does not overlap the first electrode in the first direction and a second region that overlaps the first electrode in the first direction, and a thickness of a portion of the seed layer corresponding to the second region is thicker than a thickness of a portion of the seed layer corresponding to the first region.

According to another aspect of the present disclosure, there is provided a liquid ejecting apparatus including: the liquid ejecting head according to the aspect described above, and a control portion configured to control an ejection operation from the liquid ejecting head.

### BRIEF DESCRIPTION OF THE DRAWINGS

FIG. 1 is a schematic diagram illustrating a configuration example of a liquid ejecting apparatus according to a first embodiment.

FIG. 2 is an exploded perspective view of a liquid ejecting head according to the first embodiment.

FIG. 3 is a cross-sectional view taken along a line III-III in FIG. 2.

FIG. 4 is a plan view of a part of the liquid ejecting head illustrated in FIG. 2.

FIG. 5 is a cross-sectional view taken along a line V-V in FIG. 4.

FIG. 6 is an enlarged view of a portion VI in FIG. 5.

FIG. 7 is a view illustrating an orientation of a second region of a piezoelectric layer.

FIG. 8 is a view illustrating an orientation of a first region of the piezoelectric layer.

FIG. 9 is an explanatory diagram of a method of manufacturing a liquid ejecting head according to the first embodiment.

FIG. 10 is an explanatory diagram of a method of manufacturing a liquid ejecting head according to the first embodiment.

FIG. 11 is a cross-sectional view of a liquid ejecting head according to a second embodiment.

FIG. 12 is an explanatory diagram of a method of manufacturing a liquid ejecting head according to the second embodiment.

FIG. 13 is an explanatory diagram of a method of manufacturing a liquid ejecting head according to the second embodiment.

### DESCRIPTION OF EMBODIMENTS

Hereinafter, preferred embodiments according to the present disclosure will be described with reference to the accompanying drawings. In the drawings, the dimensions and scale of each portion are appropriately different from the actual ones, and some parts are schematically illustrated for easy understanding. In addition, the scope of the present disclosure is not limited to these forms unless it is stated in the following description that the present disclosure is particularly limited.

In the following description, for the sake of convenience, the X axis, Y axis, and Z axis that intersect each other are appropriately used. In addition, in the following, one direction along the X axis is the X1 direction, and the direction opposite to the X1 direction is the X2 direction. Similarly, the directions opposite to each other along the Y axis are a Y1 direction and a Y2 direction. The Y1 direction or the Y2 direction is an example of a “first direction”. In addition, the directions opposite to each other along the Z axis are a Z1 direction and a Z2 direction. The Z1 direction is an example of the “second direction”. In the following, viewing in the Z1 direction or the Z2 direction may be referred to as “plan view”.

Here, typically, the Z axis is a vertical axis, and the Z2 direction corresponds to the downward direction in the vertical direction. However, the Z axis may not be a vertical axis. In addition, the X axis, the Y axis, and the Z axis are typically orthogonal to each other, but are not limited thereto, and may intersect at an angle within a range of, for example, equal to or more than 80° and equal to or less than 100°.

### 1: First Embodiment

### 1-1: Overall Configuration of Liquid Ejecting Apparatus

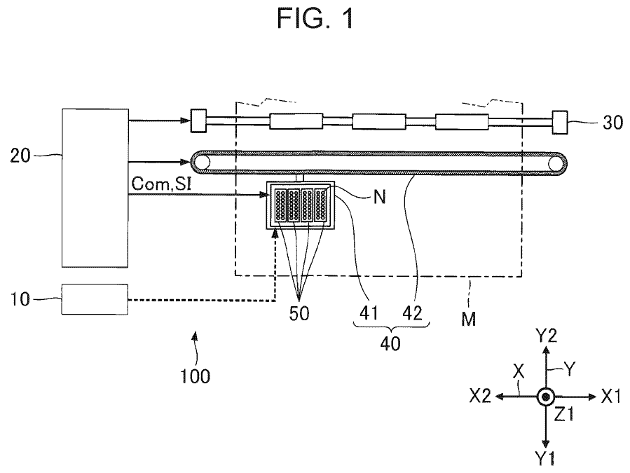

FIG. 1 is a schematic diagram illustrating a configuration example of a liquid ejecting apparatus 100 according to a first embodiment. The liquid ejecting apparatus 100 is an ink jet printing apparatus that ejects ink, which is an example of a “liquid”, onto a recording medium M as a liquid droplet. For example, the recording medium M is printing paper. The recording medium M is not limited to the printing paper, and may be, for example, a printing target of any material such as a resin film or a cloth.

As illustrated in FIG. 1, the liquid ejecting apparatus 100 includes a liquid container 10, a control module 20, a transport mechanism 30, a movement mechanism 40, and a plurality of liquid ejecting heads 50. The control module 20 is an example of a “control portion”.

The liquid container 10 stores inks. Specific aspects of the liquid container 10 include, for example, a cartridge that can be attached to and detached from the liquid ejecting apparatus 100, a bag-shaped ink pack made of a flexible film, and an ink tank that can be refilled with ink. The type of ink stored in the liquid container 10 is random.

The control module 20 controls an operation of each element of the liquid ejecting apparatus 100. For example, the control module 20 includes a processing circuit such as a central processing unit (CPU) or a field programmable gate array (FPGA) and a storage circuit such as a semiconductor memory. Here, the control module 20 outputs a drive signal Com for driving the liquid ejecting head 50 and a control signal SI for controlling the drive of the liquid ejecting head 50. The control module 20 controls an ejection operation from the liquid ejecting head 50 by the drive signal Com and the control signal SI.

The transport mechanism 30 transports the recording medium M along the Y axis under the control of the control module 20.

The movement mechanism 40 reciprocates the liquid ejecting head 50 along the X axis under the control of the control module 20. The movement mechanism 40 has a substantially box-shaped transport body 41 called a carriage that accommodates the liquid ejecting head 50, and an endless transport belt 42 to which the transport body 41 is fixed. In addition to the liquid ejecting head 50, the above-described liquid container 10 may be mounted on the transport body 41.

Each of the plurality of liquid ejecting heads 50 ejects the ink supplied from the liquid container 10 from each of a plurality of nozzles N on the recording medium M under the control of the control module 20. This ejection is performed in parallel with the transport of the recording medium M by the transport mechanism 30 and the reciprocating movement of the liquid ejecting head 50 by the movement mechanism 40, and thus an image by an ink is formed on the surface of the recording medium M.

In the example illustrated in FIG. 1, the number of liquid ejecting heads 50 is four. The number of liquid ejecting heads 50 is not limited to the example illustrated in FIG. 1, and may be any number, may be one, or may be a plurality of equal to or less than three, or equal to or more than five. In addition, the disposition of the plurality of liquid ejecting heads 50 is not limited to the example illustrated in FIG. 1, and may be any disposition.

### 1-2: Liquid Ejecting Head

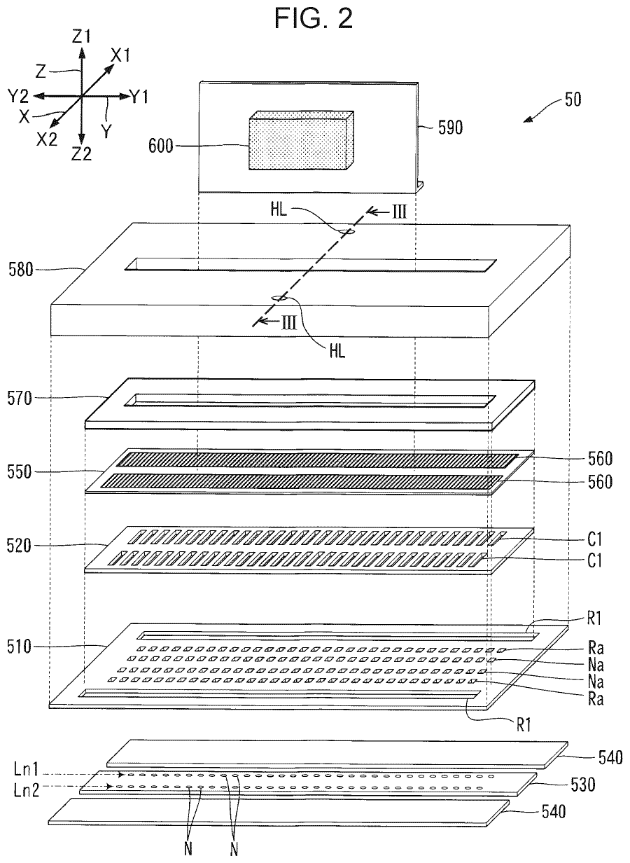

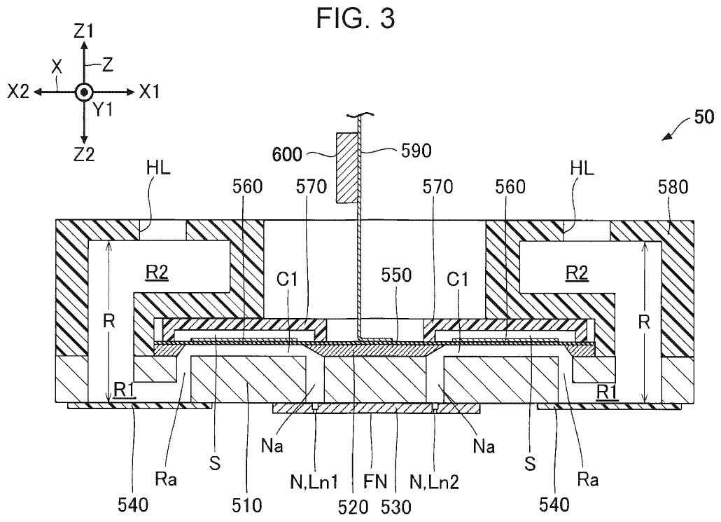

FIG. 2 is an exploded perspective view of the liquid ejecting head 50 according to the first embodiment. FIG. 3 is a cross-sectional view taken along a line III-III in FIG. 2. Hereinafter, an example of the configuration of the liquid ejecting head 50 will be described.

As illustrated in FIGS. 2 and 3, the liquid ejecting head 50 includes a plurality of nozzles N arranged in the direction along the Y axis.

The plurality of nozzles N included in the liquid ejecting head 50 are divided into a first nozzle row Ln1 and a second nozzle row Ln2 arranged at intervals in the direction along the X axis. Each of the first nozzle row Ln1 and the second nozzle row Ln2 is a set of the plurality of nozzles N linearly arranged in the direction along the Y axis.

The liquid ejecting head 50 has a configuration in which the liquid ejecting heads 50 are substantially symmetrical with each other in the direction along the X axis. However, positions of the plurality of nozzles N of the first nozzle row Ln1 and the plurality of nozzles N of the second nozzle row Ln2 in the direction along the Y axis may coincide with or may be different from each other. FIGS. 2 and 3 illustrate a configuration in which the positions of the plurality of nozzles N of the first nozzle row Ln1 and the plurality of nozzles N of the second nozzle row Ln2 coincide with each other in the direction along the Y axis.

As illustrated in FIGS. 2 and 3, the liquid ejecting head 50 includes a communication substrate 510, a pressure chamber substrate 520, a nozzle plate 530, a vibration absorbing body 540, a vibration plate 550, a plurality of piezoelectric elements 560, a protective substrate 570, a case 580, and a wiring substrate 590.

The communication substrate 510 and the pressure chamber substrate 520 are laminated in this order in the Z1 direction, and form a flow path for supplying an ink to the plurality of nozzles N. The vibration plate 550, the plurality of piezoelectric elements 560, the protective substrate 570, the case 580, the wiring substrate 590, and the drive circuit 600 are installed in a region that is positioned in the Z1 direction with respect to a laminate of the communication substrate 510 and the pressure chamber substrate 520. On the other hand, the nozzle plate 530 and the vibration absorbing body 540 are installed in a region positioned in the Z2 direction with respect to the laminated body. Each element of the liquid ejecting head 50 is approximately a plate-shaped member elongated in the Y direction, and is bonded to each other by, for example, an adhesive. Hereinafter, each element of the liquid ejecting head 50 will be described in order.

The nozzle plate 530 is a plate-shaped member provided with the plurality of nozzles N of each of the first nozzle row Ln1 and the second nozzle row Ln2. Each of the plurality of nozzles N is a through-hole through which ink is passed. Here, a surface of the nozzle plate 530 facing the Z2 direction is a nozzle surface FN. For example, the nozzle plate 530 is manufactured in such a manner that a silicon single crystal substrate is processed by a semiconductor manufacturing technique using a processing technique such as dry etching, wet etching, or the like. However, other known methods and materials may be appropriately used for manufacturing the nozzle plate 530. In addition, the cross-sectional shape of the nozzle N is typically a circular shape, but the shape is not limited thereto, and may be, for example, a non-circular shape such as a polygonal or elliptical shape.

The communication substrate 510 is provided with a flow path R1, a plurality of supply flow paths Ra, and a plurality of communication flow paths Na for each of the first nozzle row Ln1 and the second nozzle row Ln2. The flow path R1 is a flow path provided in common with the plurality of nozzles N, is a flow path communicating with the plurality of nozzles N and upstream of the nozzles N, and includes an elongated hole extending in the direction along the Y axis in a plan view viewed in the direction along the Z axis. Each of the supply flow path Ra and the communication flow path Na is a flow path including a through-hole formed for each nozzle N. Each supply flow path Ra communicates with the flow path R1.

The communication substrate 510 is manufactured by processing a silicon single crystal substrate with, for example, a semiconductor manufacturing technique, similarly to the nozzle plate 530 described above. However, other known methods and materials may be appropriately used for manufacturing the communication substrate 510.

The pressure chamber substrate 520 is a plate-shaped member in which a plurality of pressure chambers C1 called cavities are provided for each of the first nozzle row Ln1 and the second nozzle row Ln2. The plurality of pressure chambers C1 are arranged in the direction along the Y axis. Each pressure chamber C1 is an elongated space formed for each nozzle N and extending in a direction along the X axis in a plan view. As described above, the pressure chamber substrate 520 has a plurality of pressure chambers C1 arranged in the Y1 direction or the Y2 direction.

The pressure chamber substrate 520 is manufactured by processing a silicon single crystal substrate by, for example, a semiconductor manufacturing technique, similarly to the nozzle plate 530 described above. However, other known methods and materials may be appropriately used for manufacturing the pressure chamber substrate 520.

The pressure chamber C1 is positioned between the communication substrate 510 and the vibration plate 550. The plurality of pressure chambers C1 are arranged in the direction along the Y axis for each of the first nozzle row Ln1 and the second nozzle row Ln2. In addition, the pressure chamber C1 communicates with each of the communication flow path Na and the supply flow path Ra. Accordingly, the pressure chambers C1 communicate with the nozzles N through the communication flow path Na and communicate with the flow path R1 through the supply flow path Ra.

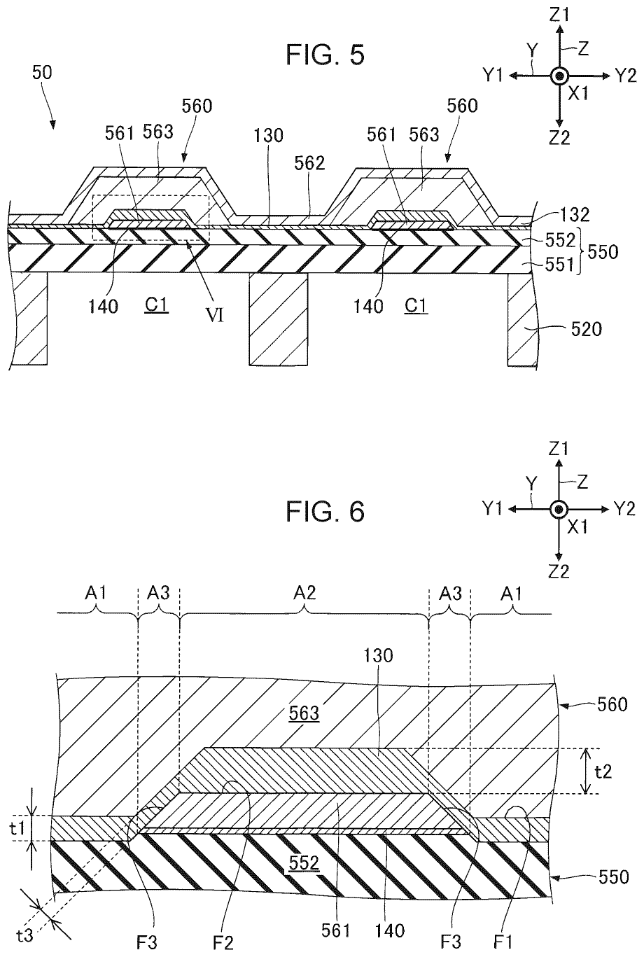

The piezoelectric element 560 is disposed on the vibration plate 550, more specifically, on the surface of the pressure chamber substrate 520 facing the Z1 direction. The vibration plate 550 is a plate-shaped member that can be elastically vibrated, and is vibrated by the piezoelectric element 560. The details of the vibration plate 550 will be described later with reference to FIG. 5.

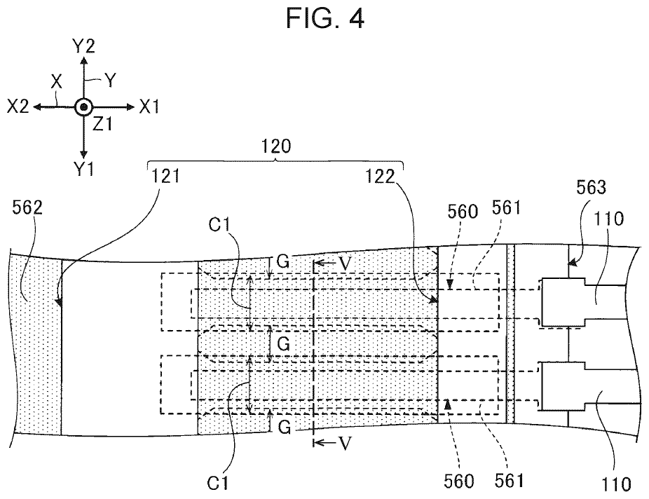

The plurality of piezoelectric elements 560 corresponding to the nozzles N are disposed on a surface of the vibration plate 550 facing the Z1 direction for each of the first nozzle row Ln1 and the second nozzle row Ln2. Each piezoelectric element 560 is a passive element that is deformed by supplying a potential corresponding to the drive signal Com, and causes pressure fluctuation in the ink in the pressure chamber C1. Each of the piezoelectric elements 560 has an elongated shape extending in the direction along the X axis in plan view. The plurality of piezoelectric elements 560 are arranged in a direction along the Y axis to correspond to the plurality of pressure chambers C1. The piezoelectric element 560 overlaps the pressure chamber C1 in plan view. The above-described piezoelectric element 560 applies pressure to the pressure chamber C1 communicating with the nozzle N that ejects the ink. Details of the piezoelectric element 560 will be described below with reference to FIGS. 4 to 6.

The protective substrate 570 is a plate-shaped member installed on the surface of the vibration plate 550 facing the Z1 direction, protects the plurality of piezoelectric elements 560, and reinforces the mechanical strength of the vibration plate 550. Here, the plurality of piezoelectric elements 560 are accommodated in a space S between the protective substrate 570 and the vibration plate 550. For example, the protective substrate 570 is made of a resin material.

The case 580 is a case for storing the ink to be supplied to the plurality of pressure chambers C1. For example, the case 580 is made of a resin material. The case 580 is provided with a flow path R2 for each of the first nozzle row Ln1 and the second nozzle row Ln2. The flow path R2 is a space coupled to the above-described flow path R1, and includes an elongated hole extending in the direction along the Y axis in a plan view viewed in the direction along the Z axis. The flow path R2 communicates with the nozzle N and functions as a reservoir R that stores the ink supplied to the plurality of pressure chambers C1 together with the flow path R1. The case 580 is provided with an inlet HL for supplying the ink to each reservoir R. The ink in each reservoir R is supplied to the pressure chamber C1 via each supply flow path Ra. The positions, the number, and other aspects of the inlets HL for each reservoir R are not limited to the examples illustrated in FIGS. 2 and 3, and are random.

The vibration absorbing body 540 is also called a compliance substrate, is a flexible resin film forming a wall surface of the reservoir R, and absorbs the pressure fluctuation in the ink in the reservoir R. The vibration absorbing body 540 may be a flexible thin plate made of metal. The surface of the vibration absorbing body 540 facing the Z1 direction is bonded to the communication substrate 510 with an adhesive or the like.

The wiring substrate 590 is mounted on a surface of the vibration plate 550 facing the Z1 direction, and is a mounting component for electrically coupling the control module 20 and the liquid ejecting head 50. For example, the wiring substrate 590 is a flexible wiring substrate such as a chip on film (COF), a flexible printed circuit (FPC), or a flexible flat cable (FFC). The drive circuit 600 is mounted on the wiring substrate 590 according to the present embodiment. The drive circuit 600 switches whether or not to supply a pulse included in the drive signal Com output from the control module 20 to each of the plurality of piezoelectric elements 560 of the liquid ejecting head 50 under the control of the control module 20. As described above, the wiring substrate 590 supplies the drive signal Com for driving the piezoelectric element 560. The wiring substrate 590 may be a rigid substrate. In this case, the drive circuit 600 is mounted on the rigid substrate or a flexible substrate coupled to the rigid substrate.

### 1-3: Piezoelectric Element

FIG. 4 is a plan view of a part of the liquid ejecting head 50 illustrated in FIG. 2. FIG. 5 is a cross-sectional view taken along a line V-V in FIG. 4. FIG. 6 is an enlarged view of a portion VI in FIG. 5. In FIG. 4, for convenience of visibility, a portion of a second electrode 562 to be described later is not covered with a second wiring 120 to be described later is dot-displayed.

Hereinafter, the configurations of the vibration plate 550 and the piezoelectric element 560 will be described with reference to FIGS. 4 to 6.

The vibration plate 550 includes a first layer 551 and a second layer 552, which are laminated in this order in the Z1 direction.

For example, the first layer 551 is an elastic film made of silicon oxide (SiO₂), and is formed by thermally oxidizing one surface of the silicon single crystal substrate. For example, the second layer 552 is an insulating film made of zirconium oxide (ZrO₂), and is formed by forming a zirconium layer by a sputtering method and thermally oxidizing the layer.

The vibration plate 550 is not limited to the above-described configuration of laminating the first layer 551 and the second layer 552, and may include, for example, a single layer, or may include equal to or more than three layers. In addition, the material of each layer constituting the vibration plate 550 is not limited to the above-described material, and may be, for example, silicon or silicon nitride. For example, as the material constituting the second layer 552, TiO₂, Al₂O₃, SiO₂, SiN, and the like can be used, in addition to ZrO₂. In addition, the size relationship between the thicknesses of the first layer 551 and the second layer 552 is not limited to the example illustrated in the drawing, and is any relationship.

The plurality of piezoelectric elements 560 are disposed on the surface of the vibration plate 550 facing the Z1 direction. As illustrated in FIG. 5, each piezoelectric element 560 includes a first electrode 561, a second electrode 562, a piezoelectric layer 563, and a seed layer 130. These are the first electrode 561, the piezoelectric layer 563, the second electrode 562, and the seed layer 130, and these are laminated in this order in the Z1 direction. As described above, the liquid ejecting head 50 includes the first electrode 561, the piezoelectric layer 563, the second electrode 562, and the seed layer 130.

In the piezoelectric element 560, the piezoelectric layer 563 is deformed by the inverse piezoelectric effect by applying a voltage between the first electrode 561 and the second electrode 562. When the vibration plate 550 vibrates in conjunction with this deformation, the pressure in the pressure chamber C1 fluctuates, which causes the ink to be ejected from the nozzle N. Here, in the piezoelectric element 560, a portion where the first electrode 561, the second electrode 562, and the piezoelectric layer 563 overlap with each other when viewed in the direction along the Z axis is an active portion, and a portion other than the active portion is an inactive portion.

As illustrated in FIG. 4, the first electrode 561 is electrically coupled to the first wiring 110, and the drive signal Com is supplied via the first wiring 110. The first wiring 110 is a lead wiring individually provided for each piezoelectric element 560, and is electrically coupled to the first electrode 561 of the corresponding piezoelectric element 560. On the other hand, the second electrode 562 is electrically coupled to the second wiring 120, and a constant potential is supplied to the second electrode 562 via the second wiring 120. The second wiring 120 is a common wiring provided in common to the plurality of piezoelectric elements 560, and is electrically coupled to the second electrode 562.

In the example illustrated in FIG. 4, the first wiring 110 is coupled to the first electrode 561, and is drawn out from the first electrode 561 toward the wiring substrate 590 for each piezoelectric element 560. On the other hand, the second wiring 120 is drawn out from above the second electrode 562 in a direction toward the wiring substrate 590 onto the vibration plate 550 at both end portions of the second electrode 562 in the Y1 direction and the Y2 direction. Here, the second wiring 120 has the strip-shaped conductive layers 121 and 122 extending in the Y1 direction. The conductive layer 121 and the conductive layer 122 are arranged at predetermined intervals in the X1 direction. Such a second wiring 120 also functions as a weight for reducing the vibration of the vibration plate 550.

The constituent materials of each of the first wiring 110 and the second wiring 120 are not particularly limited, and examples thereof include metals such as gold (Au), copper (Cu), titanium (Ti), tungsten (W), nickel (Ni), chromium (Cr), platinum (Pt), and aluminum (Al). Among these metals, gold (Au) is preferably used as a constituent material of the first wiring 110 and the second wiring 120. Here, a structure in which a layer made of gold is laminated as a surface layer on a layer made of, for example, nickel chrome is preferably used for each of the first wiring 110 and the second wiring 120.

The first electrode 561 is an individual electrode disposed on the vibration plate 550 and is disposed to be separated from each other for each piezoelectric element 560. The drive signal Com is supplied to the first electrode 561. The second electrode 562 is a strip-shaped common electrode disposed on the piezoelectric layer 563 and extending in the direction along the Y axis to be continuous over the plurality of piezoelectric elements 560. For example, the second electrode 562 is supplied with a constant potential.

Examples of the materials constituting each of the first electrode 561 and the second electrode 562 include metal materials such as platinum (Pt), aluminum (Al), iridium (Ir), nickel (Ni), gold (Au), and copper (Cu), and among these, one type may be used alone, or two or more types may be used in combination in a form of an alloy, a laminate, or the like.

In the examples illustrated in FIGS. 5 and 6, an adhesion layer 140 is disposed between the vibration plate 550 and the first electrode 561. An adhesion layer 140 is a layer for enhancing the adhesion between the first electrode 561 and the vibration plate 550, and is made of, for example, a metal such as titanium.

The piezoelectric layer 563 is disposed on the first electrode 561 and is made of a piezoelectric material. As the piezoelectric material, a composite oxide having a perovskite structure represented by a general composition formula ABO₃ is preferably used. Examples of the composite oxide include lead zirconate titanate (Pb(Zr, Ti)O₃), lead magnesium niobate-lead titanate solid solution (Pb(Mg, Nb)O₃—PbTiO₃), and the like. When the piezoelectric layer 563 contains Pb, Zr, and Ti as described above, there is an advantage that the piezoelectric characteristics of the piezoelectric layer 563 can be easily enhanced. In addition, the composite oxide is not limited to the above-described compound containing lead, and may be a compound not containing lead, for example, niobate potassium sodium ((K, Na)NbO₃, abbreviated as “KNN”), bismuth ferrite ((BiFeO₃), abbreviated as “BFO”), niobate potassium sodium lithium ((K, Na, Li)(NbO₃)), niobate tantalate potassium sodium lithium ((K, Na, Li)(Nb, Ta)O₃), bismuth manganate (BiMnO₃, abbreviated as “BM”), and the like. When the piezoelectric layer 563 contains K, Na, and Nb as described above, the piezoelectric layer 563 can be made of a material that does not contain lead.

In the example illustrated in FIG. 4, the piezoelectric layer 563 has a strip shape extending in the direction along the Y axis to be continuous over the plurality of piezoelectric elements 560. Here, the piezoelectric layer 563 is provided with a notch G that penetrates the piezoelectric layer 563 and extends in the direction along the X axis in a region corresponding to a gap between the pressure chambers C1 adjacent to each other in a plan view. The piezoelectric layer 563 may be individually provided for each piezoelectric element 560. In addition, the notch G may be a bottomed groove.

As illustrated in FIG. 6, the piezoelectric layer 563 has a first region A1, a second region A2, and a third region A3. The first region A1 is a region included in the piezoelectric layer 563, and is a region that does not overlap the first electrode 561 in the Y1 direction or the Y2 direction. In other words, the first region A1 is a region in which the range in the direction along the Y axis is different from the range of the first electrode 561 in the piezoelectric layer 563. On the other hand, the second region A2 is a region of the piezoelectric layer 563, and is a region that overlaps the first electrode 561 in the Y1 direction or the Y2 direction. In other words, the second region A2 is a region in which the range in the direction along the Y axis is the same as the range of the first electrode 561 in the piezoelectric layer 563. In addition, the third region A3 is a region included in the piezoelectric layer 563, and is a region positioned between the first region A1 and the second region A2 in the Y1 direction or the Y2 direction.

In the example illustrated in FIG. 6, the first region A1 is laminated on a region F1 that is flat along the Y1 direction or the Y2 direction of the upper surface of the vibration plate 550 when viewed in the cross section orthogonal to the X axis. The region F1 can be said to be a flat region along a virtual plane orthogonal to the Z axis of the upper surface of the vibration plate 550. On the other hand, the second region A2 is laminated on a region F2 that is flat along the Y1 direction or the Y2 direction of the upper surface of the first electrode 561 when viewed in the cross section orthogonal to the X axis. The region F2 can be said to be a flat region along a virtual plane orthogonal to the Z axis of the upper surface of the first electrode 561. The third region A3 is laminated on a region F3 that is inclined with respect to the Y1 direction or the Y2 direction of the upper surface of the first electrode 561 when viewed in the cross section orthogonal to the X axis. The region F3 can be said to be a flat region that is inclined around the X axis with respect to the virtual plane orthogonal to the Z axis of the upper surface of the first electrode 561.

The inclination angle of the region F3 with respect to the virtual plane orthogonal to the Z axis may be greater than 0° and smaller than 90°, is not particularly limited, and may be any angle. In addition, the inclination of the region F3 with respect to the virtual plane orthogonal to the Z axis is formed by, for example, adjusting the etching rate when the first electrode 561 is patterned by etching or using a grayscale mask.

The seed layer 130 is a layer positioned between the piezoelectric layer 563 and the vibration plate 550 and for controlling the orientation of the piezoelectric layer 563. The seed layer 130 is in contact with each of the first electrode 561, the vibration plate 550, and the piezoelectric layer 563, and has a crystal structure that becomes a seed crystal of the piezoelectric layer 563. As a result, the orientation of the piezoelectric layer 563 can be improved. As a result, the displacement force of the piezoelectric element 560 can be enhanced. Therefore, the ejection performance of the liquid ejecting head 50 can be enhanced.

The material constituting the seed layer 130 may be any material as long as the material has a function of controlling the orientation of the piezoelectric layer 563, but preferably contains titanium (Ti), and more preferably contains bismuth (Bi), iron (Fe), titanium (Ti), and lead (Pb). A material containing bismuth (Bi), iron (Fe), titanium (Ti), and lead (Pb) can control the orientation of the piezoelectric layer 563 as a composite oxide having a perovskite structure in which the A site contains Bi and Pb and the B site contains Fe and Ti. More specifically, the seed layer 130 is preferably made of a composite oxide represented by PbₓBi₍ₐ₋ₓ₎Fe_{y}Ti_{(b-y)}O_{z}. However, a>x and b>y. Here, it is preferable that x/(a-x) satisfies 0.04<x/(a-x)<1.40.

In the present embodiment, the seed layer 130 includes a single layer disposed over both the first region A1 and the second region A2. By disposing the seed layer 130 over both the first region A1 and the second region A2 in this manner, the orientation of the piezoelectric layer 563 can be controlled in both the active portion and the inactive portion. In addition, since the seed layer 130 includes a single layer, the number of interfaces that may cause damage such as peeling can be reduced.

A thickness t2 of the portion of the seed layer 130 corresponding to the second region A2 is thicker than a thickness t1 of the portion of the seed layer 130 corresponding to the first region A1. As a result, the crystallinity of both the first region A1 and the second region A2 of the piezoelectric layer 563 can be preferably enhanced. As a result, the occurrence of cracks in the piezoelectric layer 563 is preferably reduced. The seed layer 130 can be said to correspond to a second seed layer 132 of a second embodiment described later.

In the active portion, since the characteristics of the piezoelectric body are directly linked to the ejection characteristics as they are, it is necessary to particularly enhance the orientation in a specific plane orientation (for example, (100) orientation). In order to enhance the orientation, it is preferable to increase the thickness of the seed layer 130 made of BFTP (Bi, Fe, Ti, Pb) or the like.

On the other hand, in the inactive portion, although the piezoelectric body is formed above the upper portion thereof, the piezoelectric body is not driven because the first electrode 561 is not provided in the region. Therefore, when considering the ejection characteristics, it is not necessary to provide the seed layer 130 on the inactive portion and control the orientation of the piezoelectric body above the seed layer 130. However, when the active portion is oriented in a specific plane orientation and the inactive portion is non-oriented, a crack may occur between the active portion and the inactive portion. This is because, even when the same piezoelectric material is used, the Young's modulus and the coefficient of thermal expansion differ depending on the orientation, and the stress caused by the difference is generated between the active portion and the inactive portion.

However, even when the seed layer 130 is provided in the inactive portion and the thickness thereof is the same as or greater than that of the active portion, a problem arises in that the ejection characteristics are deteriorated or the crack generation is not improved this time.

As for the former, since the inactive portion is positioned at the end portion of the pressure chamber C1, it is required to expand or contract more significantly than the active portion. When the seed layer 130 is thickly provided in such a region, the expansion or contraction is inhibited by the thickness. As a result, the displacement of the active portion is reduced.

As for the latter, normally, the thicker the seed layer 130 is, the more improved the crystallinity of the piezoelectric layer 563 is. However, for example, in a case in which KNN is used as the material of the piezoelectric layer 563 and ZrOₓ is used as the material of the second layer 552 of the vibration plate 550, in the seed layer 130 on the second layer 552, when the thickness of the seed layer 130 is too thick, the crystallinity of the piezoelectric layer 563 may be lowered, contrary to the normal case. Therefore, when the seed layer 130 in the inactive portion is formed to have the same thickness as or a thickness greater than that of the seed layer 130 in the active portion, the piezoelectric layer 563 is directly laminated on the vibration plate 550 in the inactive portion. Therefore, the crystallinity of the piezoelectric layer 563 is significantly lowered. As a result, cracks may occur in the same manner as when the piezoelectric layer 563 in the inactive portion is non-oriented.

From such a point of view, by making the thickness t2 thicker than the thickness t1, the decrease in crystallinity of the piezoelectric layer 563 in the inactive portion as described above is reduced. Therefore, the crystallinity of both the first region A1 and the second region A2 of the piezoelectric layer 563 can be preferably enhanced.

In addition, from a viewpoint of more preferably enhancing the crystallinity of both the first region A1 and the second region A2 of the piezoelectric layer 563, the thickness t2 of the portion of the seed layer 130 corresponding to the second region A2 is preferably equal to or more than 1.2 times and equal to or less than 1.8 times the thickness t1 of the portion of the seed layer 130 corresponding to the first region A1, and more preferably equal to or more than 1.4 times and equal to or less than 1.6 times the thickness t1.

On the other hand, when the ratio of the thicknesses t2 and t1 (t2/t1) is too small, the thickness t2 is too thin, and the orientation of the second region A2 tends to decrease, or the thickness t1 is too thick, and the orientation of the first region A1 tends to decrease, depending on the combination of the material of the piezoelectric layer 563 and the material of the second layer 552 of the vibration plate 550. On the other hand, when the ratio (t2/t1) is too large, the thickness t2 is too thick, and the driving efficiency of the piezoelectric element 560 tends to decrease, or the thickness t1 is too thin, and the orientation of the first region A1 tends to decrease, depending on the combination of the material of the piezoelectric layer 563 and the material of the second layer 552 of the vibration plate 550.

The thickness t3 of the portion of the seed layer 130 corresponding to the third region A3 is preferably thinner than the thickness t1 of the portion of the seed layer 130 corresponding to the first region A1. As a result, the grain boundaries between the first region A1 or the second region A2, and the third region A3 can be aligned. On the other hand, when the thickness t3 is too thick, the orientation of the third region A3 is too high because the taper of the region F3 is present in the third region A3. Therefore, the grain boundaries between the first region A1 or the second region A2, and the third region A3 are broken.

When the above piezoelectric layer 563 is analyzed by the X-ray diffraction method (XRD) in the Z1 direction, each of the first region A1 and the second region A2 is preferentially oriented in the first plane orientation. That is, the first region A1 and the second region A2 are preferentially oriented in the same crystal plane orientation as each other. Therefore, the orientation in the plane orientation between the first region A1 and the second region A2 is not significantly different from each other. Therefore, the difference in the physical properties such as the Young's modulus and the coefficient of thermal expansion due to the difference in the plane orientation of the crystal between the first region A1 and the second region A2 of the piezoelectric layer 563 is reduced. Therefore, the possibility that a crack caused by the difference in the physical property between the first region A1 and the second region A2 is reduced. Therefore, the deterioration of the ejection performance and the durability performance can be reduced.

In the present embodiment, the first plane orientation is a (100) plane. That is, the first region A1 and the second region A2 are preferentially oriented to the (100) plane. Therefore, the ejection characteristics can be improved in the piezoelectric element 560 of the present embodiment as compared with the case where the piezoelectric element 560 is preferentially oriented in the plane orientation of the other crystals. The first plane orientation may be a (111) plane other than the (100) plane.

In addition, the orientation degree of the second region A2 in the first plane orientation is preferably high, and is more preferably equal to or more than 1.1 times and equal to or less than 1.5 times the orientation degree of the first region A1 in the first plane orientation. This is because the second region A2 is a region in which the voltage is actually applied and the strain is generated, and thus it is desired to enhance the orientation degree in the first plane orientation and enhance the displacement of the piezoelectric element 560. In addition, the orientation degree of the first region A1 in the first plane orientation does not need to be so high. On the contrary, in particular, when the orientation in the first plane orientation, particularly the orientation degree in the (100) plane, is too high, cracks may occur at the grain boundaries when a certain high voltage is applied. As a result, the breakdown voltage may be lowered. In consideration of the above point, the orientation of the first region A1 in the first plane orientation may preferably not be significantly high. From these, it is understood that the orientation degree of the second region A2 in the first plane orientation is preferably higher than the orientation degree of the first region A1 in the first plane orientation.

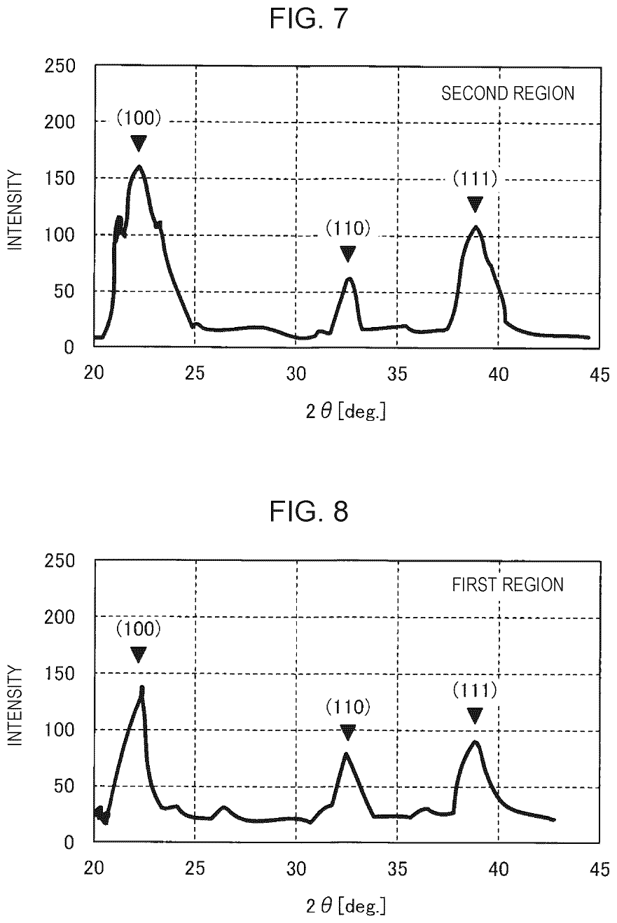

FIG. 7 is a view illustrating the orientation of the second region A2 of the piezoelectric layer 563. FIG. 8 is a view illustrating the orientation of the first region A1 of the piezoelectric layer 563. FIG. 7 illustrates a result of analyzing the second region A2 of the piezoelectric layer 563 in the Z1 direction by an X-ray diffraction method (XRD). FIG. 8 illustrates a result of analyzing the first region A1 of the piezoelectric layer 563 in the Z1 direction by an X-ray diffraction method (XRD). The results illustrated in FIGS. 7 and 8 are results when the piezoelectric layer 563 is made of KNN and the constituent material of the seed layer 130 is a composite oxide having a perovskite structure containing Bi, Pb, Fe, and Ti.

As illustrated in FIGS. 7 and 8, each of the first region A1 and the second region A2 is preferentially oriented to the (100) plane, and the difference in the orientation state between the first region A1 and the second region A2 is small.

### 1-4: Method of Manufacturing Liquid Ejecting Head

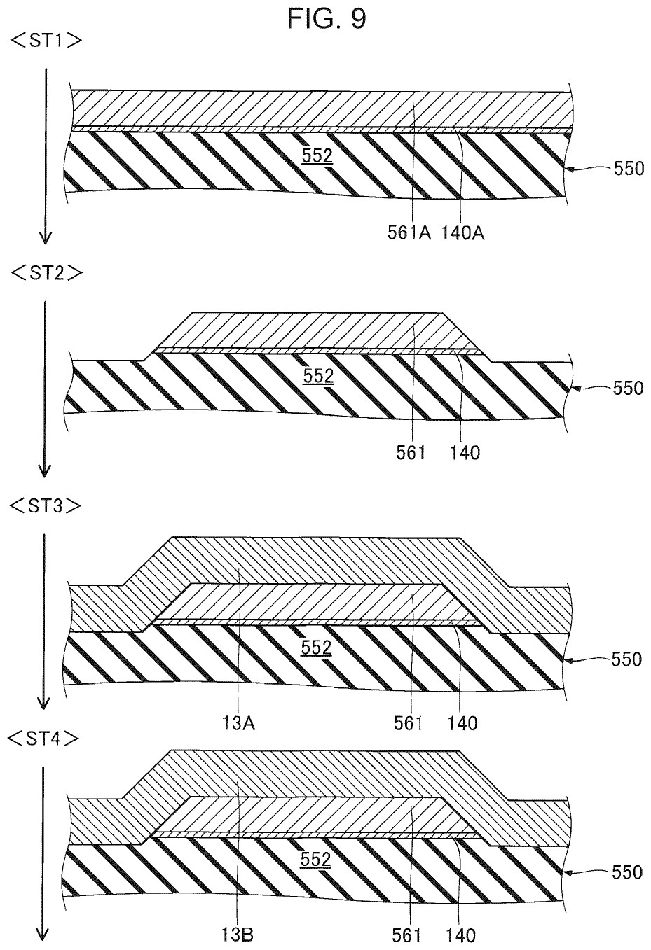

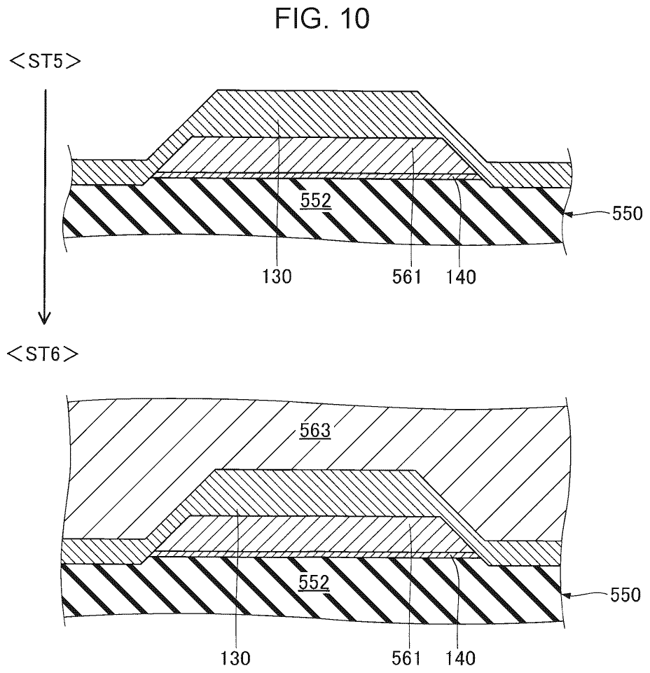

FIGS. 9 and 10 are explanatory diagrams of a method of manufacturing the liquid ejecting head 50 according to the first embodiment. As illustrated in FIGS. 9 and 10, in the method of manufacturing the liquid ejecting head 50, steps ST1 to ST6 are performed in this order. Hereinafter, each step will be described in order.

In step ST1, a layer 561A made of the material of the first electrode 561 is coated on the vibration plate 550. More specifically, in step ST1, for example, after the vibration plate 550 is formed, an adhesion layer 140A is uniformly formed by forming a metal such as titanium on the second layer 552 by a sputtering method, and then the layer 561A is uniformly formed by forming a metal such as platinum on the adhesion layer 140A by a sputtering method.

In step ST2, after step ST1, the layer 561A made of the material of the first electrode 561 is patterned. More specifically, in step ST2, the layer 561A is patterned by a known processing technique using, for example, photolithography, etching, or the like. As a result, the patterned first electrode 561 is formed. At this time, the adhesion layer 140A is patterned to form the adhesion layer 140.

In step ST3, after step ST2, a layer 13A made of the material of the seed layer 130 is coated on the vibration plate 550 and the first electrode 561. More specifically, in step ST3, for example, the layer 13A is formed by coating a solution such as an MOD solution containing a precursor material of the seed layer 130 by a spin coating method or the like over the vibration plate 550 and the first electrode 561. Here, the thickness of the layer 13A is equal to or greater than the thickness of the seed layer 130 in both the portion corresponding to the first region A1 and the portion corresponding to the second region A2.

In step ST4, the layer 13A is heat-treated after step ST3. More specifically, in step ST4, for example, the layer 13A is dried and degreased at approximately 350° C. by an oven or the like, and then heat-treated at approximately 750° C. for approximately 5 minutes by an RTA or the like. As a result, a layer 13B in which the precursor forming the layer 13A is crystallized by firing is formed. Here, the thickness of the layer 13B is equal to or greater than the thickness of the seed layer 130 in both the portion corresponding to the first region A1 and the portion corresponding to the second region A2. The conditions for the heating treatment are not limited to the above-described examples, and may be appropriately changed.

In step ST5, the seed layer 130 is formed by patterning a part of the layer 13B after step ST4. More specifically, in step ST5, for example, a portion of the layer 13B corresponding to at least the first region A1 is thinned by a known processing technique using photolithography, etching, or the like. As a result, the seed layers 130 having the thicknesses t1 and t2 as described above are formed.

In step ST6, the piezoelectric body is coated on the seed layer 130 after step ST5. More specifically, in step ST6, for example, a solution such as an MOD solution containing a precursor material of the piezoelectric body is coated by a spin coating method or the like on the seed layer 130 to form a precursor layer of the piezoelectric layer 563, and then the precursor layer is dried and degreased at approximately 350° C. by an oven or the like, and then heat-treated at approximately 750° C. for approximately 5 minutes by an RTA or the like. As a result, the piezoelectric layer 563 is formed. The piezoelectric body may be coated and heat-treated a plurality of times. In addition, the conditions of the heating treatment are not limited to the above-described examples, and may be appropriately changed.

After the above step ST6, although not illustrated, the piezoelectric layer 563 is patterned by a known processing technique using photolithography, etching, or the like. At this time, a part of the seed layer 130 is also removed by patterning so that the shape of the seed layer 130 in a plan view coincides with the shape of the piezoelectric layer 563 in a plan view. As a result, the piezoelectric element 560 is obtained. Thereafter, a liquid ejecting head 50 is obtained through a known appropriate step. The patterning of the piezoelectric layer 563 is performed, for example, after the pressure chamber C1 is formed in the pressure chamber substrate 520.

### 2. Second Embodiment

Hereinafter, a second embodiment of the present disclosure will be described. In the embodiment described below as an example, the reference numerals used in the description of the first embodiment will be assigned to elements having the same effects and functions as those of the first embodiment, and each detailed description thereof will be appropriately omitted.

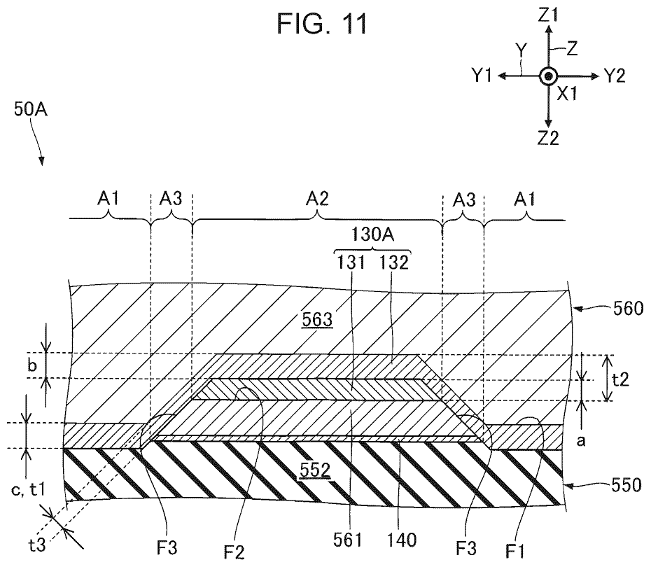

FIG. 11 is a cross-sectional view of a liquid ejecting head 50A according to a second embodiment. The liquid ejecting head 50A is configured in the same manner as the liquid ejecting head 50 of the first embodiment, except that a seed layer 130A is provided instead of the seed layer 130 of the first embodiment.

The seed layer 130A includes a first seed layer 131 and a second seed layer 132. The first seed layer 131 is not disposed in the first region A1, and is disposed in the second region A2. The second seed layer 132 is provided on the first seed layer 131 and is disposed over both the first region A1 and the second region A2. In this manner, the seed layer 130A includes the first seed layer 131 and the second seed layer 132, and thus there is an advantage that the desired thickness t1 and t2 can be easily realized.

Each of the first seed layer 131 and the second seed layer 132 is made of a material that can control the orientation of the piezoelectric layer 563 as described above. Here, since the second seed layer 132 is disposed over both the first region A1 and the second region A2, the orientation of the piezoelectric layer 563 can be controlled in both the active portion and the inactive portion. Therefore, the occurrence of damage such as cracks caused by the difference in orientation of the piezoelectric layer 563 between the active portion and the inactive portion can be reduced.

In addition, since the second seed layer 132 is provided on the first seed layer 131, as will be described in detail later, the second seed layer 132 is formed after the first seed layer 131 is formed. In addition, the first seed layer 131 can be heat-treated before patterning the first electrode 561 and the first seed layer 131. During the heat treatment, the material that can diffuse in the material of the layer such as the adhesion layer 140, directly below the first electrode 561, diffuses in the thickness direction without diffusing in the lateral direction. Therefore, the material of the layer such as the adhesion layer 140 is not concentrated and precipitated during the heat treatment. In addition, although the second seed layer 132 is heat-treated after the patterning of the first seed layer 131, during the heat treatment, the material that can be diffused among the materials of the layers such as the adhesion layer 140 is completely diffused. Therefore, the material of the layer such as the adhesion layer 140 is not concentrated and precipitated at the end portion of the first electrode 561 during the heat treatment. From the above, the occurrence of damage such as cracks caused by the occurrence of local segregation of the material of the layer such as the adhesion layer 140 can be reduced.

Here, when the first electrode 561 contains Ir, the Ir contained in the first electrode 561 is easily diffused by heat treatment. Therefore, in this case, the effect of reducing the occurrence of local segregation of the material of the layer such as the adhesion layer 140 by using the first seed layer 131 and the second seed layer 132 is significantly exhibited.

In addition, when the piezoelectric layer 563 contains K, Na, and Nb, the piezoelectric layer 563 does not contain Ti. Therefore, when the first electrode 561 contains Ti, the affinity between the first electrode 561 and the piezoelectric layer 563 is low. Therefore, when Ti diffuses from the layer such as the adhesion layer 140, Ti is precipitated at the end portion of the first electrode 561 without entering the piezoelectric layer 563. Therefore, in this case, the effect of reducing the occurrence of local segregation of the material of the layer such as the adhesion layer 140 by using the first seed layer 131 and the second seed layer 132 is significantly exhibited.

The first seed layer 131 is not disposed in the third region A3, whereas the second seed layer 132 is also disposed in the third region A3. As a result, the orientation of the third region A3 can be enhanced. Here, when the first electrode 561 and the first seed layer 131 are collectively formed by patterning, the first seed layer 131 cannot be formed in the region F3 of the first electrode 561. When the seed layer 130A is not present in the region F3, the third region A3 between the first region A1 and the second region A2 is non-oriented, so that there is a large difference in orientation between these regions. As a result, there is a possibility that cracks occur. On the other hand, by providing the second seed layer 132 on the region F3, the orientation of the third region A3 can be enhanced. As a result, the occurrence of cracks can be reduced by reducing the difference in orientation between these regions.

When the thickness of the first seed layer 131 in the second region A2 is a, the thickness of the second seed layer 132 in the second region A2 is b, and the thickness of the second seed layer 132 in the first region A1 is c, a+b>c is satisfied. As a result, the thickness t2 can be made thicker than the thickness t1.

When the thickness of the second seed layer 132 in the second region A2 is b and the thickness of the second seed layer 132 in the first region A1 is c, it is preferable that b<c is satisfied. As a result, the thickness of the seed layer 130A in the second region A2 is prevented from being thicker than necessary. As a result, the orientation control of the piezoelectric layer 563 is optimized in both the active portion and the inactive portion. Here, in the active portion, since the first seed layer 131 is present, the orientation of the piezoelectric layer 563 can be controlled by the first seed layer 131. On the other hand, in the inactive portion, since the first seed layer 131 is not present, it is necessary to perform the orientation control of the piezoelectric layer 563 by the second seed layer 132. Therefore, by making the thickness c of the second seed layer 132 in the first region A1 thicker than the thickness b of the second seed layer 132 in the second region A2, in other words, by satisfying b<c, the orientation control of the piezoelectric layer 563 is optimized in both the active portion and the inactive portion.

On the other hand, when the thickness c of the second seed layer 132 in the first region A1 is thinner than the thickness b of the second seed layer 132 in the second region A2, the thickness of the seed layer 130A in the active portion becomes too thick in performing the orientation control of the piezoelectric layer 563 in both the active portion and the inactive portion. Therefore, there is a problem that the increase in the electrical resistance of the seed layer 130A in the active portion causes a decrease in the ejection characteristic due to the deterioration of the conductivity between the first electrode 561 and the piezoelectric layer 563.

When the thickness of the first seed layer 131 in the second region A2 is a, the thickness of the second seed layer 132 in the second region A2 is b, and the thickness of the second seed layer 132 in the first region A1 is c, it is preferable that b<a<c and a+b>c are satisfied. As a result, b<c can be satisfied, and a+b>c can be satisfied, so that the difference between the thickness (a+b) and the thickness c does not become too large.

At least a part of each of the first seed layer 131 and the second seed layer 132 is in contact with the first electrode 561. The first seed layer 131 and the second seed layer 132 are obtained by forming the second seed layer 132 after the first seed layer 131 is formed.

The first seed layer 131 and the second seed layer 132 are preferably made of the same material as each other. As a result, the affinity between the first seed layer 131 and the second seed layer 132 is enhanced, and thus the adhesion between the first seed layer 131 and the second seed layer 132 can be enhanced. As a result, peeling between the first seed layer 131 and the second seed layer 132 can be reduced. On the other hand, when the first seed layer 131 and the second seed layer 132 are made of different materials, the affinity between the first seed layer 131 and the second seed layer 132 may be deteriorated, and the adhesion between the first seed layer 131 and the second seed layer 132 may be deteriorated, so that peeling between the first seed layer 131 and the second seed layer 132 may occur.

It is preferable that each of the first seed layer 131 and the second seed layer 132 contains Ti. As a result, the first seed layer 131 and the second seed layer 132 that can preferably control the orientation of the piezoelectric layer 563 can be realized.

It is preferable that each of the first seed layer 131 and the second seed layer 132 contains Bi, Fe, Ti, and Pb. As a result, since the seed layer 130A can be made of a composite oxide having a perovskite structure, the orientation of the piezoelectric layer 563 can be preferably enhanced.

When both the first seed layer 131 and the second seed layer 132 are provided, the second seed layer 132 is present in both the first region A1 and the second region A2. Therefore, each of the first region A1 and the second region A2 is preferentially oriented to the (100) plane, and the orientation states of the first region A1 and the second region A2 are very similar to each other. As described above, when both the first seed layer 131 and the second seed layer 132 are provided, the first region A1 and the second region A2 are preferentially oriented in the same crystal plane orientation as each other.

On the other hand, when only the first seed layer 131 is provided, the first seed layer 131 is present only in the second region A2, and thus the second region A2 is preferentially oriented to the (100) plane, while the first region A1 is not preferentially oriented to the (100) plane. In addition, in this case, the difference in the orientation state between the first region A1 and the second region A2 is large.

### 2-1: Method of Manufacturing Liquid Ejecting Head

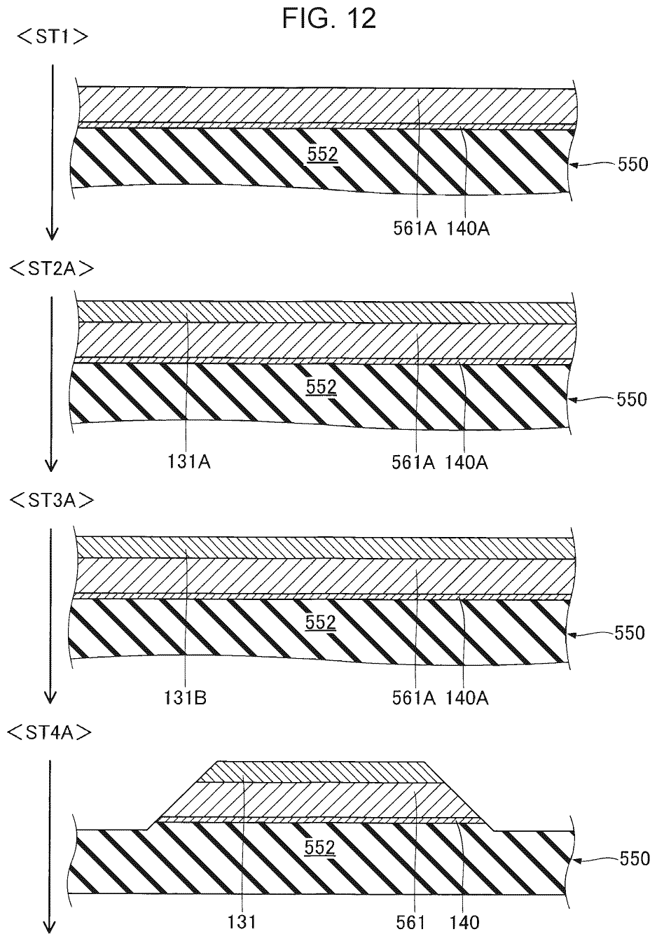

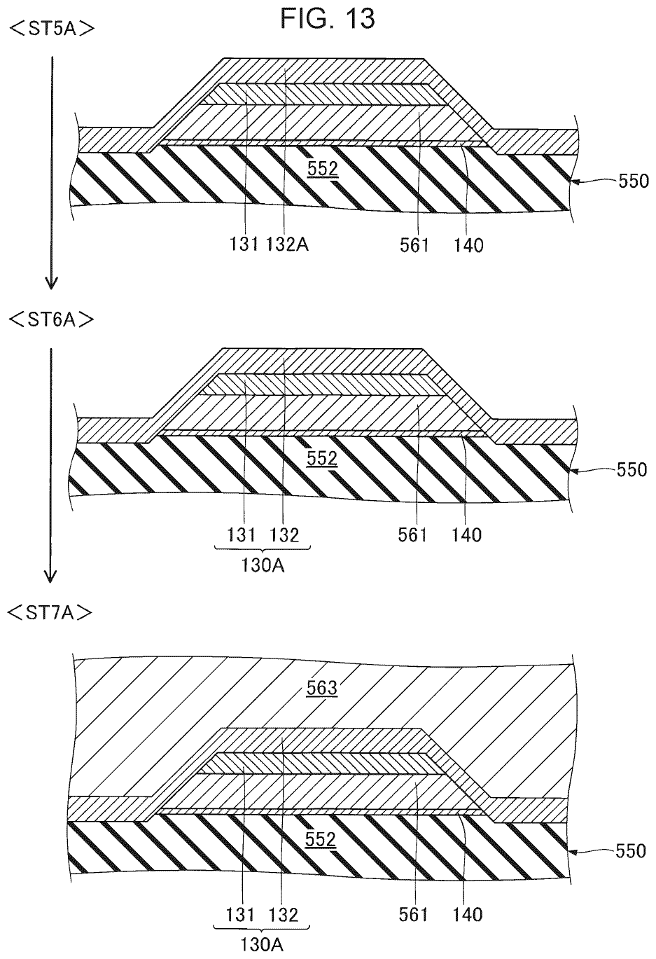

FIGS. 12 and 13 are explanatory diagrams of a method of manufacturing a liquid ejecting head 50A according to the second embodiment. As illustrated in FIGS. 12 and 13, in the method of manufacturing the liquid ejecting head 50A, steps ST1A to ST7A are performed in this order. Hereinafter, each step will be described in order.

In step ST1A, a layer 561A made of the material of the first electrode 561 is coated on the vibration plate 550, as in step ST1 of the first embodiment.

In step ST2A, after step ST1A, a layer 131A made of the material of the first seed layer 131 is coated on the layer 561A made of the material of the first electrode 561. More specifically, in step ST2A, for example, a solution such as an MOD solution containing a precursor material of the first seed layer 131 is coated by a spin coating method or the like on the layer 561A to form the layer 131A, which is a precursor layer of the first seed layer 131.

In step ST3A, after step ST2A, the layer 131A made of the material of the first seed layer 131 is heat-treated. More specifically, in step ST3A, for example, the layer 131A, which is a precursor layer of the first seed layer 131, is dried and degreased at approximately 350° C. by an oven or the like, and then heat-treated at approximately 750° C. for approximately 5 minutes by rapid thermal annealing (RTA) or the like. As a result, a layer 131B in which the precursor forming the layer 131A is crystallized by firing is formed. The conditions for the heating treatment are not limited to the above-described examples, and may be appropriately changed.

In step ST4A, after step ST3A, the layer 561A made of the material of the first electrode 561 and the layer 131B made of the material of the first seed layer 131 are patterned. More specifically, in step ST4A, for example, the layer 561A and the layer 131B are collectively patterned by a known processing technique using photolithography, etching, or the like. As a result, the patterned first electrode 561 is formed, and the patterned first seed layer 131 is formed. At this time, the adhesion layer 140A is patterned to form the adhesion layer 140.

In step ST5A, after step ST4A, a layer 132A made of the material of the second seed layer 132 is coated on the vibration plate 550 and the first seed layer 131 (the layer made of the material of the first seed layer 131). More specifically, in step ST5A, for example, a solution such as an MOD solution containing a precursor material of the second seed layer 132 is coated by a spin coating method or the like over the vibration plate 550 and the first seed layer 131 to form the layer 132A which is a precursor layer of the second seed layer 132.

In step ST6A, after step ST5A, the layer 132A made of the material of the second seed layer 132 is heat-treated. More specifically, in step ST6A, for example, the layer 132A, which is a precursor layer of the second seed layer 132, is dried and degreased at approximately 350° C. by an oven or the like, and then heat-treated at approximately 750° C. for approximately 5 minutes by RTA or the like. As a result, the second seed layer 132 in which the precursor forming the layer 132A is crystallized by firing is formed. The conditions for the heating treatment are not limited to the above-described examples, and may be appropriately changed. In addition, the conditions such as the temperature and the time of the heating treatment in step ST6A may be the same as or different from the conditions of the heating treatment in step ST3A.

In step ST7A, after step ST6A, the piezoelectric body is coated on the second seed layer 132 (the layer made of the material of the second seed layer 132). More specifically, in step ST7A, for example, a solution such as an MOD solution containing a precursor material of a piezoelectric body is coated by a spin coating method or the like on the second seed layer 132 to form a precursor layer of the piezoelectric layer 563, and then the precursor layer is dried and degreased at approximately 350° C. by an oven or the like, and then heat-treated at approximately 750° C. for approximately 5 minutes by an RTA or the like. As a result, the piezoelectric layer 563 is formed. The piezoelectric body may be coated and heat-treated a plurality of times. In addition, the conditions of the heating treatment are not limited to the above-described examples, and may be appropriately changed.

After the above step ST7A, although not illustrated, the piezoelectric layer 563 is patterned by a known processing technique using photolithography, etching, or the like. At this time, a part of the second seed layer 132 is also removed by patterning so that the shape of the second seed layer 132 in a plan view coincides with the shape of the piezoelectric layer 563 in a plan view. As a result, the piezoelectric element 560 is obtained. Thereafter, a liquid ejecting head 50 is obtained through a known appropriate step. The patterning of the piezoelectric layer 563 is performed, for example, after the pressure chamber C1 is formed in the pressure chamber substrate 520.

In the above method of manufacturing the liquid ejecting head 50, the heating treatment of step ST3A is performed before the patterning of step ST4A. During the heating treatment, the material such as Ti that can diffuse in the material of the layer such as the adhesion layer 140A, directly below the layer 561A, diffuses in the thickness direction without diffusing in the lateral direction. Therefore, during the heating treatment, the material of the layer such as the adhesion layer 140A is not concentrated and precipitated. In addition, although the heating treatment for the second seed layer 132 is performed in step ST6A after the patterning in step ST4A, during the heating treatment, the material of the layer such as the adhesion layer 140, which can be diffused, is completely diffused in step ST3A. Therefore, during the heating treatment, the material of the layer such as the adhesion layer 140 is not concentrated and precipitated at the end portion of the first electrode 561. From the above, the occurrence of cracks caused by the occurrence of local segregation of the material of the layer such as the adhesion layer 140 can be reduced.

### 3: MODIFICATION EXAMPLE

Each embodiment in the above illustration can be variously modified. Specific modification aspects that can be applied to each of the embodiments described above are exemplified below. The aspects randomly selected from the following examples can be appropriately merged to the extent that these aspects do not contradict each other.

### 3-1: Modification Example 1

In the above-described embodiment, an aspect in which the second electrode 562 is the common electrode is illustrated, but the present disclosure is not limited to this aspect, and the second electrode 562 may be an individual electrode for each piezoelectric element 560. In this case, the first electrode 561 may be a common electrode common to the plurality of piezoelectric elements 560. However, even when the first electrode 561 is used as the common electrode and the second electrode 562 is used as the individual electrode, the piezoelectric layer 563 includes a region that does not overlap the first electrode 561.

### 3-2: Modification Example 2

In each of the above-described embodiments, the serial type liquid ejecting apparatus 100 in which the transport body 41 having the liquid ejecting head 50 mounted thereon is reciprocated is exemplified, but the present disclosure can also be applied to a line type liquid ejecting apparatus in which the plurality of nozzles N are distributed over the entire width of the recording medium M.

### 3-3: Modification Example 3

The liquid ejecting apparatus 100 exemplified in the above-described embodiments may be adopted in various apparatuses such as a facsimile machine and a copier, in addition to an apparatus dedicated to printing, and the application of the present disclosure is not particularly limited. However, the application of the liquid ejecting apparatus is not limited to printing. For example, a liquid ejecting apparatus that ejects a solution of a coloring material is used as a manufacturing apparatus that forms a color filter of a display device such as a liquid crystal display panel. In addition, a liquid ejecting apparatus that ejects a solution of a conductive material is used as a manufacturing apparatus that forms a wiring or an electrode on a wiring substrate. In addition, a liquid ejecting apparatus that ejects a solution of an organic substance related to a living body is used, for example, as a manufacturing apparatus that manufactures a biochip.

What is claimed is:

1. A liquid ejecting head comprising:
a pressure chamber substrate that includes a plurality of pressure chambers arranged in a first direction;
a vibration plate disposed on the pressure chamber substrate;
a first electrode disposed on the vibration plate;
a piezoelectric layer disposed on the first electrode;
a second electrode disposed on the piezoelectric layer; and
a seed layer positioned between the piezoelectric layer and the vibration plate and configured to control an orientation of the piezoelectric layer, wherein
the piezoelectric layer has a first region that does not overlap the first electrode in the first direction and a second region that overlaps the first electrode in the first direction, and
a thickness of a portion of the seed layer corresponding to the second region is thicker than a thickness of a portion of the seed layer corresponding to the first region.

2. The liquid ejecting head according to claim 1, wherein
the thickness of the portion of the seed layer corresponding to the second region is equal to or more than 1.2 times and equal to or less than 1.8 times the thickness of the portion of the seed layer corresponding to the first region.

3. The liquid ejecting head according to claim 2, wherein
the thickness of the portion of the seed layer corresponding to the second region is equal to or more than 1.4 times and equal to or less than 1.6 times the thickness of the portion of the seed layer corresponding to the first region.

4. The liquid ejecting head according to claim 1, wherein
the seed layer includes a single layer disposed over both the first region and the second region.

5. The liquid ejecting head according to claim 1, wherein
the seed layer includes a first seed layer that is not disposed in the first region and is disposed in the second region, and
a second seed layer that is provided on the first seed layer and is disposed over both the first region and the second region.

6. The liquid ejecting head according to claim 1, wherein
when the piezoelectric layer is analyzed by an X-ray diffraction method, the first region is preferentially oriented in a first plane orientation, and the second region is preferentially oriented in the first plane orientation, and
an orientation degree of the second region in the first plane orientation is higher than an orientation degree of the first region in the first plane orientation.

7. The liquid ejecting head according to claim 6, wherein
the orientation degree of the second region in the first plane orientation is equal to or more than 1.1 times and equal to or less than 1.5 times the orientation degree of the first region in the first plane orientation.

8. The liquid ejecting head according to claim 6, wherein
the first plane orientation is (100).

9. The liquid ejecting head according to claim 1, wherein
the piezoelectric layer contains K, Na, and Nb.

10. The liquid ejecting head according to claim 1, wherein
the piezoelectric layer contains Pb, Zr, and Ti.

11. The liquid ejecting head according to claim 1, wherein
the first region is a region laminated on a flat region along the first direction of an upper surface of the vibration plate, and
the second region is a region laminated on a flat region along the first direction of an upper surface of the first electrode.

12. The liquid ejecting head according to claim 11, wherein
the piezoelectric layer further includes a third region positioned between the first region and the second region in the first direction, and
the third region is laminated on a region of the upper surface of the first electrode that is inclined with respect to the first direction.

13. The liquid ejecting head according to claim 12, wherein
a thickness of a portion of the seed layer corresponding to the third region is thinner than the thickness of the portion of the seed layer corresponding to the first region.

14. A liquid ejecting apparatus comprising:
the liquid ejecting head according to claim 1; and
a control portion configured to control an ejection operation from the liquid ejecting head.
